(19) United States
(12) Patent Application Publication
(10) Pub. No.: US 2006/0017133 A1
(43) Pub. Date: Jan. 26, 2006

(54) Electronic part-containing elements, electronic devices and production methods

(75) Inventors: Kiyoshi Oi, Nagano-shi (JP); Yasuyoshi Horikawa, Nagano-shi (JP); Akihito Takano, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 11/188,723

(22) Filed: Jul. 26, 2005

(30) Foreign Application Priority Data
Jul. 26, 2004 (JP) 2004-217625

(51) Int. Cl. H01L 29/00

(52) U.S. Cl. 257/528; 438/329; 257/700; 257/924

(57) ABSTRACT

An electronic part-containing element used by being incorporated in an electronic device, in which the electronic part-containing element comprises an insulating support member which does not take part in the constitution of the electronic device but is removed in the process of producing the electronic device, and a circuit module supported by the support member, and the circuit module contains one or more electronic parts, each in the form of a thin film, therein and has connection terminals for the electronic part at least on the surface thereof that comes into contact with the support member.

### BACKGROUND OF THE INVENTION

1. Field of the Invention

The present invention relates to an electronic part-containing or built-in element used, while being buried in, for example, a wiring board, in the production of electronic devices such as semiconductor devices, to a method of producing the same, to an electronic device incorporating the electronic part-containing element of the present invention, and to a method of producing the same.

2. Description of the Related Art

In recent years, to satisfy the requirements of high performance, high degree of function, small size and decreased weight of electronic equipments and other devices, efforts have been made to improve both the constitution of the devices and the production processes concerning semiconductor devices and other electronic devices. In semiconductor devices, for example, it is a widely accepted practice to very densely mount active elements such as semiconductor elements and passive elements such as capacitors and resistors, in order to decrease the thickness, size and weight of the devices.

For example, Japanese Unexamined Patent Publication (Kokai) No. 2002-261449 discloses a part-containing module having a multi-layer wiring structure and incorporating active elements and passive elements therein. Referring to FIG. 1, the part-containing module has a core layer 105. The core layer 105 includes an electrically insulating layer 102 made of a composite material of an inorganic filler and a thermosetting resin, and a wiring pattern 100. On the wiring pattern 100, there are mounted a bare semiconductor chip (active part) 101 and a chip part (passive part) 104. The wiring patterns 100 are electrically connected together through inner viaholes 103. Reference numerals 106, 107, and 108 denote electrically insulating layers, inner viaholes and wiring patterns, respectively.

In the above part-containing module, however, ready-made active parts and passive parts are buried therein causing a problem of an increased thickness of the layer in which parts having large thicknesses are buried. In practice, the obtained part-containing module has a thickness of about 1000 μm hindering an effort to decrease the thickness of the packages (generally, of the order of about 100 to 1,000 μm) that has been demanded in recent years.

Further, Japanese Unexamined Patent Publication (Kokai) No. 2002-164467 discloses a circuit block body formed on a mother board so as to be peeled off and a method of its production. FIG. 2 illustrates a state after a circuit block body 202 is separated from a mother board 201. The circuit block body 202 can be produced through a step of forming a peeling layer 206 on the main flat surface of the mother board 201 made of an Si board 205, a step of forming insulating layers 207, 209 and 214 on the peeling layer 206, a step of forming wiring layers 208, 211 and 216 on the respective insulating layers, and a step of separating the circuit block body 202 from the mother board 201 via the peeling layer 206. The circuit block body 202 has a resistor 212, a capacitor 213 and an inductor 217, which are passive elements, buried therein, during the process of production, by relying upon a thin-film technology. The circuit block body 202 is capable of mounting a semiconductor chip (not shown) on the surface thereof. Reference numerals 210 and 215 denote viaholes.

However, the following problems exist when the passive elements are fabricated between the layers and in the core during the process of producing the semiconductor device according to the above-mentioned method.

1) The production process can be carried out only under low-temperature conditions and cannot be adapted to a high-temperature production process of not lower than 200° C. that has been demanded in recent years.

2) The passive elements must be formed by using the whole surface of the motherboard to increase the cost of production due to the use of an expensive material for forming the passive elements.

3) Each passive element is formed through a different process and, hence, it is difficult to form a circuit (an LCR circuit) mounting, for example, an inductor, a capacitor and a resistor in one build-up layer.

### SUMMARY OF THE INVENTION

The present invention is directed to solve the above-mentioned prior art problems, and has an object to provide an electronic device which highly densely mounts active elements such as semiconductor elements and passive elements such as resistors and capacitors making it possible to decrease the thickness, size and weight of the device, contributing to decreasing the thickness of the package, permitting a low-temperature production process to be applied, and making it possible to form an LCR circuit in one build-up layer without using the whole surface of the substrate for forming the passive elements, as well as a novel electronic part-containing element useful for the manufacture of the electronic devices.

It is further an object of the present invention to provide a method useful for the production of an electronic part-containing element and an electronic device.

The above and other objects of the present invention will be easily understood from the following detailed description of the present invention.

According to one aspect of the present invention, there is provided an electronic part-containing or -built in element used by being incorporated in an electronic device, in which the electronic part-containing element comprises a support member which does not take part in the constitution of the electronic device but is removed in the process of producing the electronic device, and a circuit module supported by the support member, and in which the circuit module contains one or more electronic parts each in the form of a thin film therein and comprises connection terminals for the electronic parts at least on the surface thereof that comes into contact with the support member.

According to another aspect of the present invention, there is provided a method of producing an electronic part-containing element used by being incorporated in an electronic device, which comprises:
providing a support member which does not take part in the constitution of the electronic device but is removed in the process of producing the electronic device; and
forming a circuit module on the support member, in which one or more electronic parts are fabricated by utilizing a thin film-forming technology in the circuit module while the circuit module is being formed, and connection terminals for the electronic parts are formed at least on the surface of the circuit module that comes into contact with the support member.

According to a further aspect of the present invention, there is provided an electronic device incorporating one or more electronic parts, each in the form of a thin film, wherein the electronic part is a part of an electronic part-containing circuit module that is formed by incorporating, in any portion of the electronic device, an electronic part-containing element which comprises a circuit module containing the electronic part therein and a support member supporting the circuit module, and has connection terminals for the electronic parts at least on the surface of the circuit module that comes into contact with the support member and, thereafter, by removing the support member in the step of producing the electronic device.

According to a still further aspect of the present invention, there is provided a method of producing an electronic device incorporating one or more electronic parts each in the form of a thin film, comprising:
incorporating, in any portion of the electronic device, an electronic part-containing element which comprises a circuit module containing the electronic part therein and a support member supporting the circuit module, and has connection terminals for the electronic parts at least on the surface of the circuit module that comes into contact with the support member; and
providing an electronic part-containing circuit module by removing the support member in the process of producing the electronic device.

As will be appreciated from the following detailed description of the present invention, the present invention does not rely upon the widely used conventional method of successively fabricating the electronic parts, i.e., active elements such as semiconductor elements and passive elements such as resistors and capacitors in producing the electronic device. Instead, the present invention allows production of an electronic part-containing element of the unit type, into which the above parts have been incorporated already, by relying on a separate production process and incorporates the electronic part-containing element in any stage in a process of producing an electronic device, achieving various distinguished effects that could not be expected from the conventional technology.

For example, by using the electronic part-containing element of the unit type, it is possible to highly densely mount active elements such as semiconductor elements and passive elements such as resistors and capacitors, making it possible to decrease the thickness, size and weight of the electronic device. When practically used, further, the support member has been removed from the electronic part-containing element (functional portions only are selectively used) making it possible to reduce the thickness of the electronic devices.

The electronic part-containing element of the unit type can be produced in advance and preserved, offering such an advantage that they can be readily offered as required. From the side of the user, further, important portions in the process for producing the electronic device can be shifted to the ready-made electronic part-containing element, offering advantages of decreasing the areas required for the production lines and for the production site and decreasing the cost of production.

Further, the electronic part-containing element is produced by a separate process making it possible to eliminate the waste in the material that is used and to decrease the cost of production. Besides, as the electronic parts need not be in-site buried, parts having a variety of functions can be selected to complete the electronic part-containing element. For example, application of a material having a high dielectric constant that requires a high-temperature processing and mounting of the LCR composite circuit can be carried out during the process for producing the electronic part-containing element, instead of the in-site application and mounting, it becomes possible to widen a variation of the process for producing the electronic devices. Application of the low-temperature production process also helps to widen an application width for producing the electronic devices.

Moreover, as the electronic parts have been buried already in the electronic part-containing element, the electrically conductive viaholes for electric conduction and the through electrodes can be easily provided for the electronic parts at the time of producing the electronic device.

By using the electronic part-containing element of the unit type, further, there is no need to use the whole surface of the substrate for forming the individual electronic parts, and the LCR circuit can be formed in one build-up layer.

### BRIEF DESCRIPTION OF THE DRAWINGS

FIG. 1 is a sectional view illustrating a conventional part-containing module;

FIG. 2 is a sectional view illustrating a conventional circuit block body;

FIG. 3 is a sectional view illustrating a preferred embodiment of an electronic part-containing element according to the present invention;

FIG. 4 is a sectional view illustrating another preferred embodiment of the electronic part-containing element according to the present invention;

FIG. 5 is a sectional view illustrating a further preferred embodiment of the electronic part-containing element according to the present invention;

FIGS. 6A to 6F are sectional views illustrating, in sequence, a preferred method of producing the electronic part-containing element according to the present invention;

FIG. 7 is a sectional view illustrating a preferred embodiment of an electronic device according to the present invention;

FIG. 8 is a sectional view illustrating another preferred embodiment of the electronic device according to the present invention;

FIG. 9 is a sectional view illustrating a further preferred embodiment of the electronic device according to the present invention;

FIG. 10 is a sectional view illustrating a still further preferred embodiment of the electronic device according to the present invention;

FIG. 11 is a sectional view illustrating a yet further preferred embodiment of the electronic device according to the present invention;

FIGS. 12A to 12E are sectional views illustrating, in sequence, a method of producing an electronic device by using the electronic part-containing element of the present invention;

FIGS. 13A to 13G are sectional views illustrating, in sequence, another method of producing the electronic device by using the electronic part-containing element of the present invention;

FIGS. 14A to 14G are sectional views illustrating, in sequence, a further method of producing the electronic device by using the electronic part-containing element of the present invention; and

FIGS. 15A to 15E are sectional views illustrating, in sequence, a method of producing the electronic device by using the electronic part-containing element of FIG. 5.

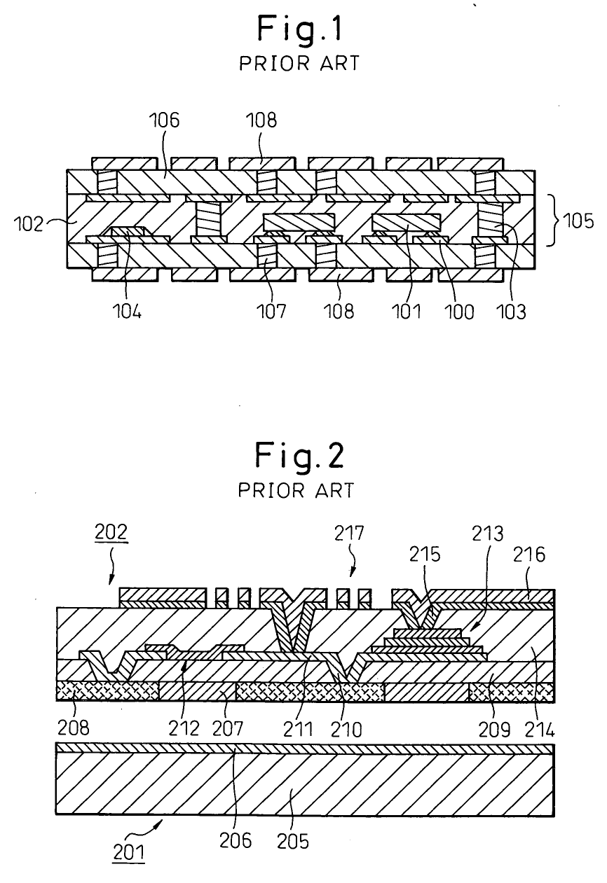

### DESCRIPTION OF THE PREFERRED EMBODIMENTS

The electronic part-containing element, the electronic device and their production methods according to the present invention can be advantageously carried out in a variety of embodiments. The present invention will now be described with reference to representative embodiments to which the invention is in no way limited.

The present invention, first, resides in an electronic part-containing element that is used by being incorporated in an electronic device. Here, the “electronic part” encompasses a variety of parts usually used in the field of electronic equipment and, as required, may encompass any other parts typically, however, representing active elements such as semiconductor elements like ICs, LSIs and passive elements like inductors (Ls), capacitors (Cs) and resistors (Rs). In the electronic part-containing element, the active element and the passive element may be used alone, or two or more kinds of these elements may be used in any combination.

Further, when used in the specification of this application, the term “electronic device” encompasses an apparatus, device, equipment and the like having at least one kind of the above-mentioned electronic parts in any portion thereof. That is, the electronic device of the present invention contains at least one electronic part-containing element of the invention in a state from which the support member has been removed and, though arbitrary, contains one or more additional electronic parts like those described above.

Desirably, the electronic part-containing element can be incorporated in a layer such as a core layer or a build-up layer in the electronic device. As the electronic part-containing element has a thickness (inclusive of the thickness of the electrodes), after the support member has been removed therefrom, of usually about not larger than 50 μm and generally in the range of about 10 to 50 μm, it can contribute to decreasing the thickness of the electronic device. As required, further, the electronic part-containing elements may be incorporated, as two or more kinds in parallel, in one layer of the electronic device or may, further, be incorporated simultaneously in any of two or more layers when the electronic device has a multi-layer structure. Though not necessarily limited to those described below, suitable electronic devices comprise wiring boards inclusive of multi-layer wiring boards and build-up wiring boards, semiconductor devices, semiconductor packages and the like.

The electronic part-containing element according to the present invention comprises, at least:
(1) a support member which does not take part in the constitution of the electronic device but is removed in the step of producing the electronic device; and
(2) a circuit module supported by the support member.

In the electronic part-containing element of the present invention, the support member is used for temporarily supporting the sheet-like circuit module and is, desirably, made of an insulating material. Further, by taking into consideration the fact that the support member does not take part in the constitution of the electronic device but is removed in the step of producing the electronic device, it is desired that the support member is made of a material that can be easily removed in the step of producing the electronic device. Usually, it is desired to form the support member by using an inorganic or organic insulating material that can be removed by polishing or the like. Though not limited to those described below, the support member suited for putting the invention into practice includes inorganic material boards such as a silicon board (desirably having an SiO₂ coating), a ceramic board and a glass board, as well as organic resin boards such as a glass epoxy resin board, a polyimide resin board and a phenol resin board. The thickness of the support member can vary over a wide range depending upon the constitutions of the electronic part-containing element and the electronic device and upon the production conditions, but is, usually, in a range of about 100 to 1,000 μm.

The circuit module is desirably in the form of a sheet, and contains therein at least one electronic part in the form of a thin film. The electronic parts are, as described above, active elements such as semiconductor elements, and passive elements such as inductors (inductor wirings), capacitors and resistors. In the practice of the invention, desirably, a passive element is used as the electronic part. The passive element may be used alone, or two or more kinds of passive elements may be used in a composite form like an LCR circuit. In the case of the present invention, desirably, two or more kinds of passive elements can be arranged in parallel in one layer in the electronic part-containing element.

Desirably, further, the electronic part is incorporated in the circuit module in the form of a thin-film part. The electronic part that is formed and used in the form of a thin film is effective in decreasing the thickness, size and weight of the electronic device. Basically, the thin-film part can be formed by relying, basically, upon a thin film-forming technology that has heretofore been widely used, such as plating, electrodeposition, sputtering, vacuum evaporation, coating or lamination.

The circuit module has, in addition to the electronic part, connection terminals for connecting the electronic part to the electronic parts outside of the circuit module, to the wiring pattern layer (wiring circuit) or to the connection terminals. The connection terminals are usually formed by using a conducting metal such as copper or aluminum. For connecting the electronic part to the external unit, the connection terminals are at least arranged on the surface which is the main surface of the circuit module that comes in contact with the support member. When the connection terminals are arranged on the surface of the circuit module of only the side of the support member, the other surface of the circuit module is usually covered with an insulating material. When necessary, the circuit module has the connection terminals arranged on both surfaces thereof, i.e., on the first surface of the circuit module on the side of the support member and on the second surface on the side opposite to the first surface that comes in contact with the support member.

The circuit module can further possess through electrodes formed therein. Upon incorporating through electrodes in the circuit module, no detouring wiring is required. As a result of shortening the wiring, therefore, the characteristics can be improved and the cost of production can be decreased.

The circuit module can further have any constituent components necessary for forming the circuit module or the electronic device in addition to having the electronic parts, connection terminals and through electrodes. Suitable constituent components may include, for example, wiring circuits and electrodes. These constituent components, too, can be formed in any pattern by using a conducting metal such as copper or the like. The electrodes may be utilized as the connection terminals.

In the circuit module, further, the electronic parts and the connection terminals are usually isolated from each other relying on any insulating technology, and it is particularly recommended to apply an insulating layer. To form the insulating layer, there may be applied an insulating material such as a polyimide resin or an epoxy resin, or an insulating film of such a resin may be laminated in combination with the incorporation of the electronic parts and the connection terminals.

As required, the electronic part-containing element can possess additional layers in addition to the support member and the circuit module. For example, when the electronic part in the electronic part-containing element requires a higher precision, the support member and the circuit module are not directly joined together but, instead, an etching-resistant barrier layer and an etch-out layer are successively formed on the surface of the circuit module that comes in contact with the support member. For example, the barrier layer can be formed by using any etching-resistant metal material such as chromium capable of protecting the underlying circuit module from the etching at the time of removing the upper etch-out layer by etching. The thickness of the barrier layer can be varied over a wide range but is, usually, about 0.01 to 1 μm. The etch-out layer can be easily formed by using a metal material that can be etched out, such as copper or nickel. The thickness of the etch-out layer can be varied over a wide range but is, usually, about 0.1 to 10 μm.

Second, the present invention resides in a method of producing an electronic part-containing element of the invention that is used by being incorporated in the electronic device described above.

The method of producing an electronic part-containing element of the invention can be carried out in a variety of ways and, preferably, through the steps of:
(1) forming a support member which does not take part in the constitution of the electronic device but is removed in the step of producing the electronic device; and
(2) forming a circuit module on the support member.

In the method of the present invention, the support member is formed by forming an insulating board such as a silicon board maintaining a desired thickness. The surfaces of the support member that is formed can receive, as required, a chemical treatment or a mechanical treatment. When, for example, the electrodes are formed on the support member by plating copper, nonelectrolytic copper plating may be applied to the surfaces of the support member to facilitate the copper plating.

After the support member is formed, the circuit module of the constitution described above is fabricated on one surface thereof by any method. In fabricating the circuit module, it is desired that at least one electronic part is formed therein relying upon the thin film-forming technology. Here, further, it is desired that at least the connection terminals for the electronic part are formed on the surface of the circuit module that comes in contact with the support member.

The method of producing the electronic part-containing element will be further described. In the case of a composite circuit having passive elements which are an inductor, a capacitor and a resistor, for example, the electronic part-containing element can be advantageously produced through the procedure described below.

First, an inductor is formed on an insulating board formed as the support member. The inductor is usually formed simultaneously with the wiring circuits and electrodes that are formed on the same plane and can, hence, be advantageously formed by utilizing ordinary wiring-forming technology. For instance, the inductor comprising a copper wiring or an aluminum wiring is formed by applying a photoresist maintaining a predetermined thickness onto the insulating board, patterning the resist film by the photolithographic method to form a resist pattern having openings at portions where the inductors and electrodes are to be formed, filling copper or aluminum in the openings portions by plating. Upon peeling and removing the used resist pattern, the inductors and wirings are completed on the insulating board.

Next, on the insulating board on which the inductor is fabricated, there is formed a capacitor at a portion avoiding the inductor. The capacitor is constituted by a dielectric layer and electrodes (upper electrode and lower electrode) holding it. The dielectric layer of the capacitor can be formed by using various dielectrics, depending upon the constitution of the capacitor, by relying upon various film-forming methods. When the capacitor is formed by using such a dielectric as STO, BST or BTO, there can be employed sputtering, CVD or sol-gel method. Further, when the capacitor is to be formed by using such a dielectric as Ta₂O₅ or Al₂O₃, there can be used anodic oxidation such as of Ta or Al. Further, when the capacitor is to be formed by using a resin material containing such a ferroelectric filler as BTO filler or the like, there can be used lamination, dispensing, electrodeposition and coating. The thickness of the dielectric layer of the capacitor can be varied over a wide range but is, usually, in a range of about 0.01 to 10 μm. Further, the electrodes holding the dielectric layer can be formed by using an electrically conducting metal such as copper like the inductor wiring. The thickness of the electrodes can be varied over a wide range but is, usually, in a range of about 1 to 10 μm.

After the capacitor is formed as described above, a resistor is formed on a portion that is remaining on the insulating board. The resistor can be formed by using various resistance material depending upon the constitution of the resistor by using various film-forming method. When the resistor is to be formed from such a resistance material as TaN or Pt, there can be used sputtering, CVD or sol-gel method. When the resistor is to be formed by using a carbon resistance material, there can be used vacuum evaporation. Further, when the resistor is to be formed by using a resin material such as a carbon paste, there can be used lamination, dispensing, electrodeposition and coating. Further, when the resistor is formed by using a thin nickel film, there can be used, for example, a nonelectrolytic nickel-plating solution. The thickness of the resistor can be varied over a wide range but is, usually, in a range of about 1 to 10 μm.

After the composite circuit of the inductor, capacitor and resistor is formed as described above, an insulating layer is formed on the uppermost layer of the resulting electronic part-containing element. The insulating layer can be formed by using a method that is generally used for the production of electronic devices. The insulating layer can be formed by using such an insulating resin material as polyimide resin or epoxy resin by relying upon lamination, press-forming or coating. Or, the insulating layer can be formed by using such an inorganic insulating material as SiO₂, Al₂O₃, Ta₂O₃, SiN or AlN by relying upon sputtering or CVD. The thickness of the resistor can be varied over a wide range but is, usually, in a range of about 0.01 to 1 μm.

Third, the present invention resides in an electronic device incorporating at least one electronic part in the form of a thin film. Here, the terms “electronic part” and “electronic device” are as defined above.

The electronic device of the present invention at least comprises an electronic part-containing element of the invention. That is, at least one electronic part is in the electronic part-containing element of the invention comprising a circuit module containing the electronic part therein, and a support member supporting the circuit module, and having connection terminals for the electronic part at least on the surface of the circuit module that comes in contact with the support member. In the electronic device of the present invention, the electronic part-containing element is incorporated in any portion of the electronic device and, thereafter, the support member only is separated and removed from the circuit module. The electronic device of the invention incorporates, at any position therein, an electronic part originated from the electronic part-containing element, as well as an electronic part necessary for constituting the electronic device depending upon the constitution of the electronic device, such as active element, passive element, or any other part or wiring circuit, electrodes conducting viaholes or external connection terminals. For example, the electronic part can be electrically connected to a conducting pattern such as a wiring circuit or electrodes through the conducting viaholes.

The circuit module incorporated in the electric device of the present invention is produced together with the support member which temporarily supports it but is removed from the circuit module during the step of producing the electronic device desirably based upon the method described above through a process separate from the process for producing the electronic device. Therefore, the circuit module produced and incorporated on the site through the process for producing the electronic device lies outside the scope of the present invention.

As described above, the electronic device of the present invention can assume various constitutions and forms. In the practice of the invention, for instance, the electronic part-containing circuit module separated from the electronic part-containing element of the present invention can be incorporated as one member of the wiring board that constitutes the electronic device. When the wiring board is the multi-layer wiring board, the electronic part-containing circuit module can be incorporated in the uppermost layer or the core layer of the multi-layer wiring board or in both the uppermost layer and the core layer. The uppermost layer and the core layer may, respectively, incorporate therein the electronic part-containing circuit module alone or may incorporate therein two or more kinds of electronic part-containing circuit modules in combination.

In incorporating the electronic part-containing circuit module in the multi-layer wiring board or in other electronic devices, various methods can be used. At a given timing during the production of the electronic device, for instance, the electronic part-containing element (circuit module side) of the invention may be fixed to the member (e.g., core layer, build-up layer, etc., hereinafter also referred to as “underlying layer”) that has been formed already for constituting the electronic device and, immediately thereafter or after a step in a subsequent stage, the support member that becomes an obstacle to the electronic device is removed. According to another method, there is formed a board for temporary mounting such as a rigid board that can be removed in a subsequent step, the electronic part-containing element (circuit module side) of the invention is fixed onto the rigid board, and a wiring circuit and an insulating layer necessary for completing the electronic device are successively laminated thereon to incorporate the electronic part. Here, the support member of the electronic part-containing element can be removed in any stage in the process for producing the electronic device, and the board for temporary mounting, too, can be removed in any state in the process for producing the electronic device.

The electronic part-containing element can be fixed to the underlying layer or to the board for temporary mounting based on various methods. Generally, the electronic part-containing element can be advantageously fixed via a fixing member such as a die-attachment film or a burying resin or a fixing member such as a double-sided tape. As required, the electronic part-containing element can be fixed by using a die-bonding method which is generally employed for the production of electronic devices instead of using the fixing material.

Fourth, the present invention resides in a method of producing an electronic device of the invention incorporating at least one electronic part in the form of a thin film.

The method of producing the electronic device according to the present invention can be carried out in various ways, and is preferably carried out according to a method which comprises:
(1) incorporating, in any portion of the electronic device, an electronic part-containing element which includes a circuit module containing the electronic part therein and a support member supporting the circuit module, and has at least connection terminals for the electronic part formed on the surface of the circuit module that comes in contact with the support member; and
(2) providing an electronic part-containing circuit module by removing the support member in the step of producing the electronic device.

In the practice of the method of the present invention, the electronic part-containing element used in the step (1) is advantageously produced by the method which comprises the steps of:
forming a support member which does not take part in the constitution of the electronic device but is removed in the step of producing the electronic device; and
forming a circuit module on the support member in which at least one electronic part is fabricated by utilizing a thin film-forming technology in the circuit module while the circuit module is being formed, and connection terminals for the electronic part are formed at least on the surface of the circuit module that comes in contact with the support member.

The constitution of the electronic part-containing element, the support member used therein and the electronic part are as described above in detail.

In the method of producing the electronic part-containing element, the steps of forming the support member and of forming the circuit module are usually conducted successively. As required, however, one or more additional steps may be included after the support member is formed and, thereafter, the circuit module may be formed. For example, when a high degree of precision is required for the part, an etch-out layer and a barrier layer may be formed successively on the support member that is formed as described earlier. The etch-out layer and the barrier layer are temporarily used like the support member, and must be removed in any stage in the process for producing the electronic device.

According to the method of the present invention, the electronic part-containing circuit module is provided by removing the support member in the step of producing the electronic device that has been fabricated in the preceding steps. The step of removing the support member can be carried out in any stage in the process for producing the electronic device after the electronic part-containing element has been formed but is, generally, carried out immediately after the formation of the electronic part-containing element or after the electronic part-containing element is sealed with an insulating resin. That is, after the electronic part-containing element is fixed to the substrate (which in this invention is called underlying layer or the board for temporary mounting, but which, as required, may be any other constituent member) in a manner that the support member is exposed upward, the electronic device is completed through a subsequent series of processing step and machining step, and the support member is removed in any stage of the processing step or machining step for completing the electronic device.

Reverting to the step (1), the electronic part-containing element can be advantageously incorporated in any portion of the electronic device in various ways.

As described above, for example, the electronic part-containing element is fixed on the circuit module side thereof to the underlying layer (e.g., core layer, build-up layer, etc.) of the electronic device that has been formed already via, desirably, a fixing material, and a wiring circuit and an insulating layer necessary for completing the electronic device are successively formed thereon, and the electronic part is incorporated.

Concretely, for example, a wiring board mounting a semiconductor element as an electronic device is presumed here and, the electronic part-containing circuit module is incorporated as a member of the wiring board at the time of forming the wiring board. When the wiring board is a multi-layer wiring board, the electronic part-containing circuit module is incorporated in the uppermost layer or the core layer of the multi-layer wiring board. Further, in order to electrically connect the electronic part to the conducting pattern such as wiring circuit or electrodes, there may be utilized conducting viaholes formed by filling the through holes with a conducting metal.

According to an alternative method, there is formed a board for temporary mounting, such as a rigid board and, thereafter, the electronic part-containing element (circuit module side) is fixed onto the rigid substrate via a fixing material, a wiring circuit and an insulating layer necessary for completing the electronic device is successively laminated thereon, and an electronic part is incorporated. The electronic part may be mounted on the electronic device that is completed relying on a flip-chip method or a wiring-bonding method.

### EXAMPLES

Next, examples of the present invention will now be described with reference to the accompanying drawings. It should be noted that the present invention is not limited to these examples only.

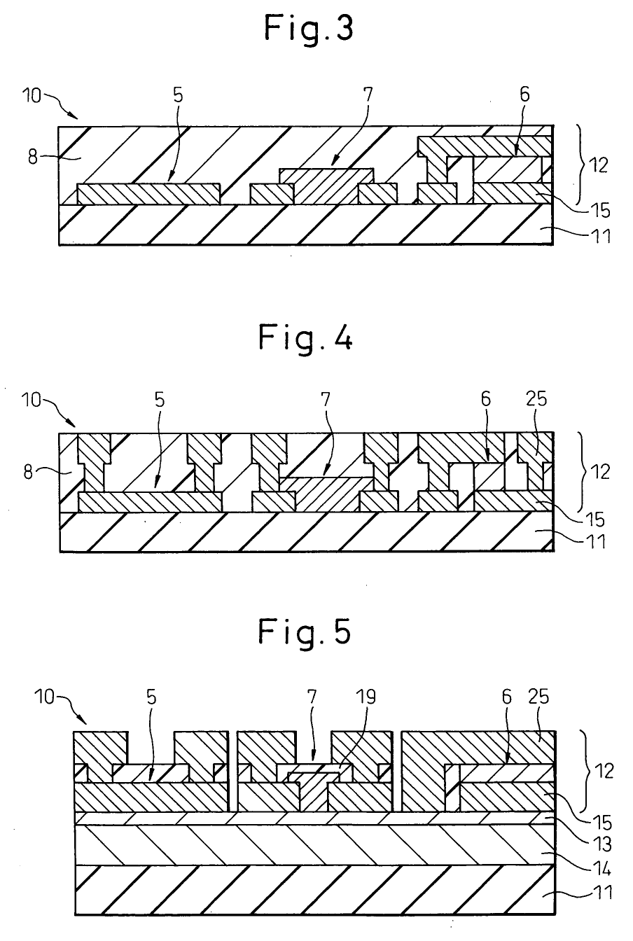

FIG. 3 is a sectional view illustrating a preferred embodiment of the electronic part-containing element of the present invention. The electronic part-containing element 10 comprises a support member 11 and a sheet-like circuit module 12 supported thereby. The support member 11 is removed in the step of producing an electronic device. A glass board is used in this embodiment. The circuit module 12 includes a composite circuit (LCR circuit) of a spiral inductor 5, a capacitor 6 and a resistor 7. The LCR circuit is in the form of a thin film as shown and contributes to decreasing the size of the device. Of the surfaces of the circuit module 12, the surface that comes in contact with the support member 11 is provided with a connection terminal (lower electrode) 15.

In the illustrated electronic part-containing element 10, the inductor 5 and the lower electrode 15 are the copper wirings formed by laminating and patterning a copper foil. The capacitor (dielectric layer) 6 comprises a Ta₂O₅ formed by the anodic oxidation of tantalum (Ta). The resistor 7 is a sputtered film of TaN. The inductor 5, capacitor 6 and resistor 7 are covered with an insulating film 8 of an epoxy resin.

FIG. 4 is a sectional view illustrating another preferred embodiment of the electronic part-containing element of the present invention. Like that of FIG. 3, the electronic part-containing element 10 comprises a support member 11 of a glass board, and a sheet-like circuit module 12 supported thereby. The circuit module 12 includes a composite circuit (LCR circuit) of a spiral inductor 5, a capacitor 6 and a resistor 7. The circuit module 12 has a connection terminal (lower electrode) 15 on the surface thereof that comes in contact with the support member 11, and has a connection terminal (upper electrode) 25 on the upper surface thereof.

In the illustrated electronic part-containing element 10, the inductor 5 and the lower electrode 15 are the copper wirings formed by laminating and patterning a copper foil. The capacitor (dielectric layer) 6 comprises a Ta₂O₅ formed by the anodic oxidation of tantalum (Ta). The upper electrode 25 is the copper wiring formed by plating copper. The resistor 7 is a sputtered film of TaN. The inductor 5, capacitor 6 and resistor 7 are covered with an insulating film 8 of an epoxy resin.

FIG. 5 is a sectional view illustrating another preferred embodiment of the electronic part-containing element according to the present invention. Like those of FIGS. 3 and 4, the electronic part-containing element 10 comprises a support member 11 of a glass board, and a sheet-like circuit module 12 supported thereby. The circuit module 12 includes a composite circuit (LCR circuit) of a spiral inductor 5, a capacitor 6 and a resistor 7. The circuit module 12 has a connection terminal (lower electrode) 15 on the surface thereof that comes in contact with the support member 11, and has a connection terminal (upper electrode) 25 on the upper surface thereof. Between the support member 11 and the circuit module 12, there are provided a barrier layer 13, which is a thin chromium layer formed by sputtering, and an etch-out layer 14 formed by plating copper.

In the illustrated electronic part-containing element 10, the inductor 5 and the lower electrode 15 are the copper wirings formed by laminating and patterning a copper foil. The capacitor (dielectric layer) 6 comprises a Ta₂O₅ formed by the anodic oxidation of tantalum (Ta). The upper electrode 25 is the copper wiring formed by plating copper. The resistor 7 is a sputtered film of TaN. The resistor 7 is covered with an insulating layer 19 of an epoxy resin.

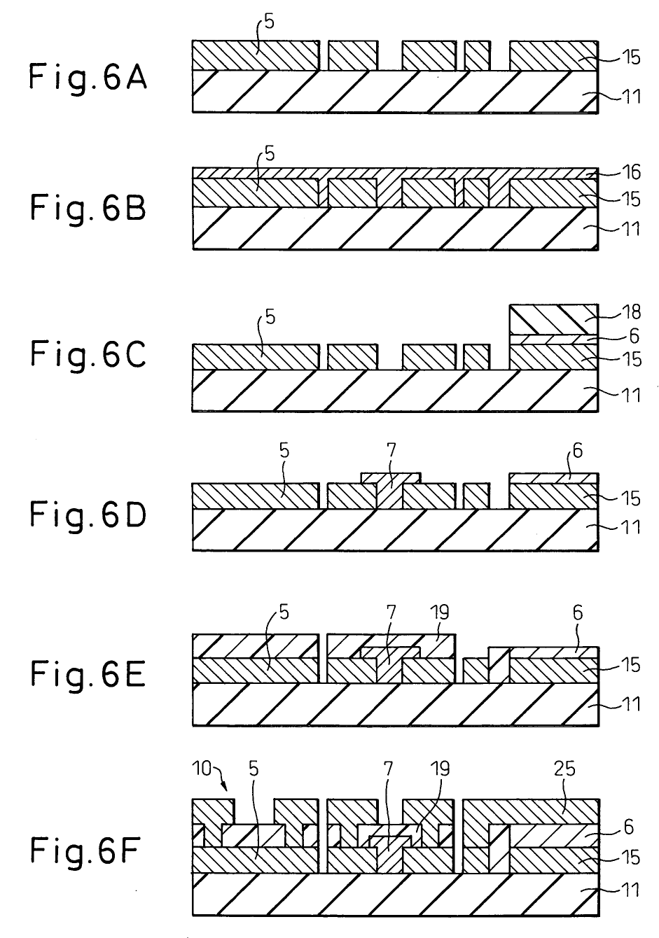

FIGS. 6A to 6F are sectional views illustrating, successively, a preferred method of producing the electronic part-containing element of the present invention. As will be understood, the illustrated electronic part-containing element 10 has a structure similar to that of the electronic part-containing element 10 of FIG. 5 but has neither the barrier layer nor the etch-out layer between the support member 11 and the circuit module 12.

First, as shown in FIG. 6A, a spiral inductor (wiring) 5 is formed on a glass board 11 formed as a support member. The inductor 5 can be formed by forming a copper foil on the surface of the glass board 11, followed by etching. Simultaneously with this, there are formed other wiring circuit and a lower electrode 15 for the capacitor on the same plane. The inductor 5 may be formed by forming a conducting layer relying upon the nonelectrolytic plating of copper and electrolytic plating of copper instead of forming the copper foil, followed by etching.

Next, to form a dielectric layer of the capacitor, a Ta layer 16 is formed on the glass board 11 on which the inductor 5 has been fabricated, as shown in FIG. 6B. The Ta layer 16 can be deposited as a thin film by sputtering Ta. The Ta layer 16 is anodically oxidized by a conventional method so as to be converted into a dielectric (Ta₂O₅).

After the dielectric (Ta₂O₅) is formed, the dielectric layer 6 of Ta₂O₅ is etched in the presence of a resist mask 18 as shown in FIG. 6C, to remove unnecessary portions (portions other than the capacitor). After the resist mask 18 is peeled and removed, there is exposed the dielectric layer 6 which is a part of the capacitor.

After the capacitor is formed as described above, a resistor 7 is formed as shown in FIG. 6D. The resistor 7 can be formed by, for example, sputtering TaN. Through a series of these steps, a composite circuit of the inductor, capacitor and resistor is formed on the glass board.

Thereafter, to protect the element that is formed, an insulating layer 19 is formed on the inductor 5 and the resistor 7 as shown in FIG. 6E. The insulating layer 19 can be formed by, for example, laminating the epoxy resin.

Finally, as shown in FIG. 6F, the upper electrode for completing the capacitor 6 is formed by plating copper. As shown, further, an opening is formed in the insulating layer 19 so as to reach the wiring such as the inductor 5, copper is plated so as to fill the opening, and copper wiring is also formed simultaneously by plating with copper.

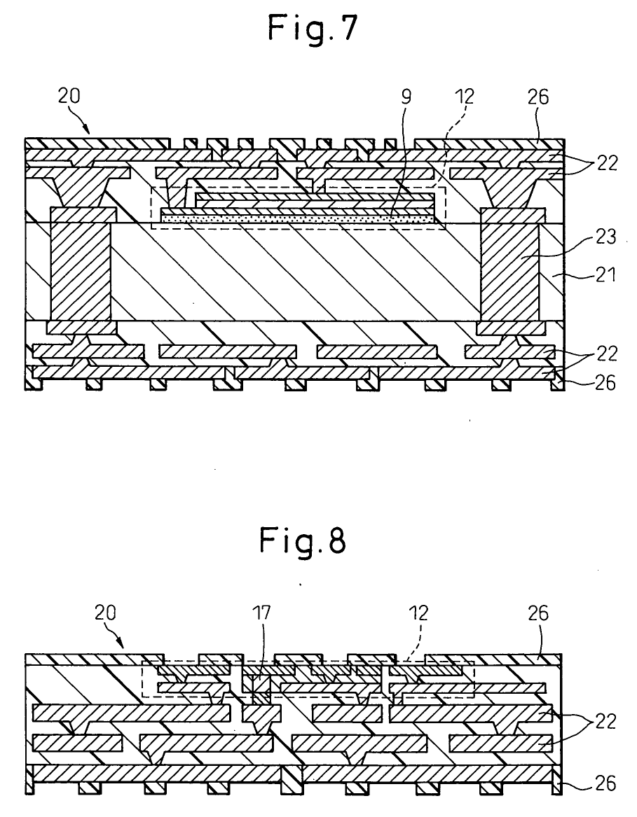

FIG. 7 is a sectional view illustrating a preferred embodiment of an electronic device according to the present invention. A build-up wiring board 20 illustrated includes a core layer 21 of a composite insulating resin, and build-up wiring layers 22 formed by plating copper on both surfaces thereof via an insulating layer of an insulating resin. The upper and lower wiring layers 22 are electrically connected together through conducting viaholes 23 formed by filling the through holes with copper that is plated as shown. In the case of the shown build-up wiring board 20, a circuit module (electronic part-containing element from which the support member has been removed) 12 of the invention is fabricated on one surface of the core layer 21 via a fixing material 9 which is a die-attachment film. The circuit module 12 has a thickness which is as thin as about 50 μm and is incorporated in one build-up wiring layer as shown. The shown build-up wiring board 20 has an insulating layer 26 in the form of a pattern as the uppermost layer thereof. Though not shown, a semiconductor element such as an LSI chip, a passive element such as a chip capacitor and any other electronic part can be mounted on the uppermost layer of the build-up wiring board 20 relying upon the flip-chip connection method or the wire-bonding method. Or, the shown build-up wiring board 20 can be mounted on the other wiring board via solder balls or the like.

FIG. 8 is a sectional view illustrating another preferred embodiment of the electronic device according to the present invention. The illustrated build-up wiring board 20 includes build-up wiring layers 22 formed by plating copper via an insulating layer of an insulating resin. In the case of the shown build-up wiring board 20, a circuit module (electronic part-containing element from which the support member has been removed) 12 of the invention is fabricated in the uppermost layer. The shown circuit module 12 has a through electrode 17 formed by plating copper to penetrate therethrough. The through electrode 17 does not require the formation of the detour wiring and makes it possible to shorten the wiring and to improve the characteristics. Further, the circuit module 12 has a thickness which is as very thin as about 50 μm and is incorporated in one build-up wiring layer as shown. The illustrated build-up wiring board 20 has an insulating layer 26 in the form of a pattern as the uppermost layer thereof. Though not shown, a semiconductor element such as an LSI chip, a passive element such as a chip capacitor and any other electronic part can be mounted on the circuit module 12 contained in the build-up wiring board 20 relying upon the flip-chip connection. Further, the shown build-up wiring board 20 can be mounted on the other wiring board via solder balls or the like.

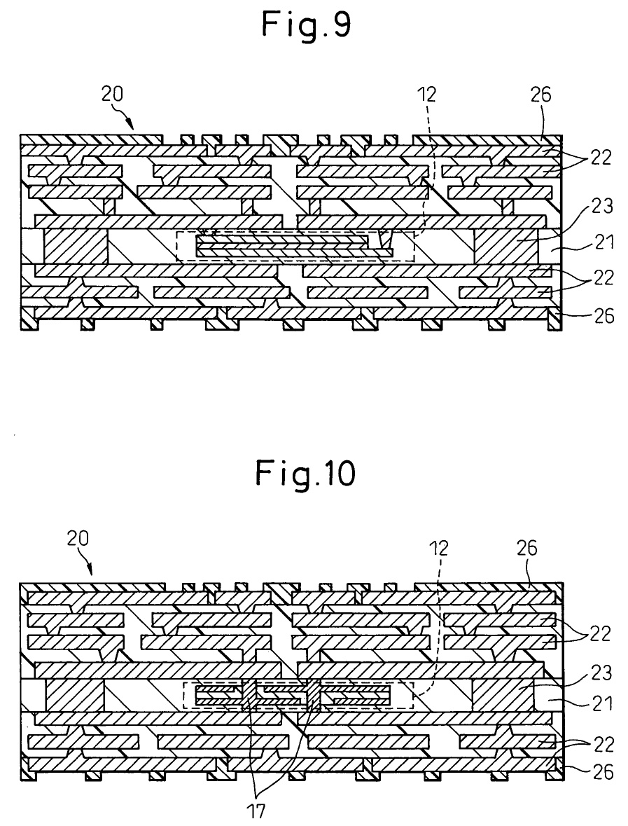

FIG. 9 is a sectional view illustrating a further preferred embodiment of the electronic device according to the present invention. The illustrated build-up wiring board 20 includes a core layer 21 of a composite insulating resin, and build-up wiring layers 22 formed by plating copper on both surfaces thereof via an insulating layer of an insulating resin. The upper and lower wiring layers 22 are electrically connected together through conducting viaholes 23 formed by filling the through holes with copper that is plated as shown. In the case of the shown build-up wiring board 20, a circuit module (electronic part-containing element from which the support member has been removed) 12 of the invention is fabricated in the core layer 21. In the illustrated embodiment, one circuit module (thickness of about 50 μm) is fabricated nearly at the central portion of the core layer 21 but it may be fabricated in other portion as required or it may be fabricated in a number of two or more. The shown build-up wiring board 20 has an insulating layer 26 in the form of a pattern as the uppermost layer thereof. Though not shown, a semiconductor element such as an LSI chip, a passive element such as a chip capacitor and any other electronic part can be mounted on the uppermost layer of the build-up wiring board 20 relying upon the flip-chip connection or the wire-bonding method. Or, the shown build-up wiring board 20 can be mounted on the other wiring board via solder balls or the like.

FIG. 10 is a sectional view illustrating a further preferred embodiment of the electronic device according to the present invention. The illustrated build-up wiring board 20 is constituted in the same manner as the build-up wiring board 20 of FIG. 9. In the case of the build-up wiring board 20 of this embodiment, the circuit module 12 contained in the core layer 21 further has through-type electrodes 17. The through-type electrodes 17 provided in the circuit module 12 make it possible to omit the detouring wiring, shorten the wiring and to improve the characteristics, which are the additional effects.

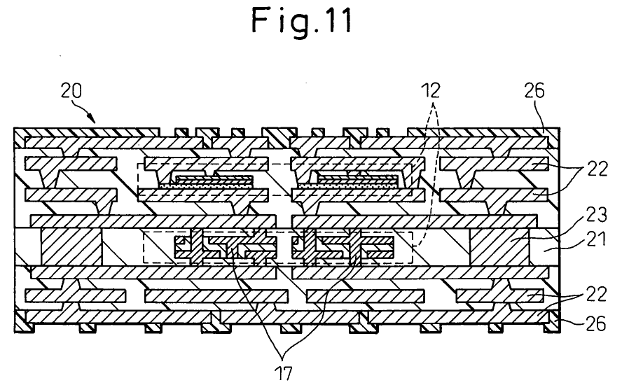

FIG. 11 is a sectional view illustrating a further preferred embodiment of the electronic device according to the present invention. The illustrated build-up wiring board 20 is constituted in the same manner as the build-up wiring board 20 of FIG. 10. In the case of the build-up wiring board 20 of this embodiment, two circuit modules 12 each having the through electrode 17 are contained in the core layer 21 and, besides, another two circuit modules 12 are fabricated in one build-up wiring layer. Upon containing a total of four circuit modules 12, the build-up wiring board 20 exhibits further enhanced characteristics.

The electronic devices (build-up wiring boards) of the invention shown in FIGS. 7 to 11 can be produced by burying the electronic circuit-containing element and, particularly, the circuit module of the present invention, by various methods.

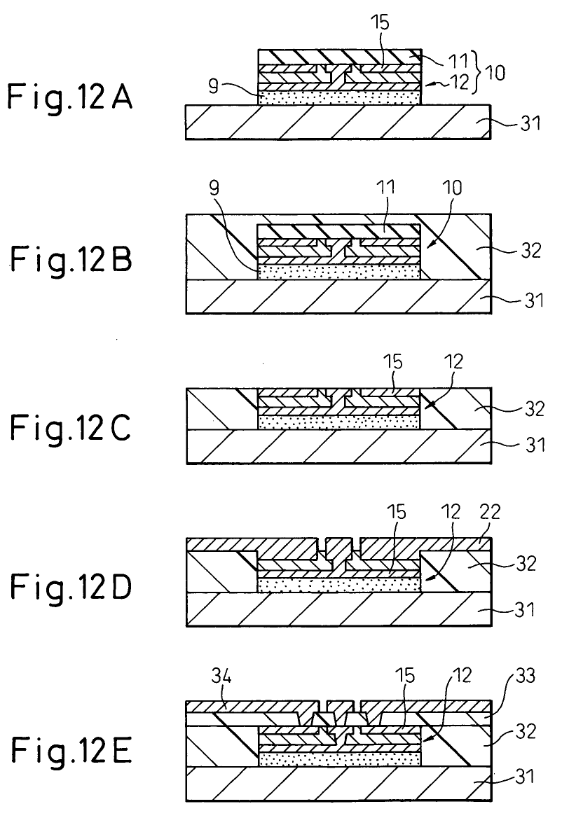

FIGS. 12A to 12E are sectional views illustrating, successively, a method of producing the electronic device of FIG. 7 by using the electronic part-containing element of the present invention.

Referring, first, to FIG. 12A, the electronic part-containing element 10 of the invention is placed on an underlying layer 31 that has been formed in advance with the support member 11 on the upper side, and is fixed thereto by using a fixing material 9 which is a die-attachment film. In the case of this embodiment, the underlying film 31 is a core layer of the multi-layer wiring board.

Referring, next, to FIG. 12B, the underlying layer 31 is covered with an insulating resin 32 to seal the electronic part-containing element 10. The insulating resin used here may be a resin material that is usually used for forming an interlayer insulating film in the production of electronic devices and may be, for example, an ABF resin manufactured by Ajinomoto Co.

Referring, next, to FIG. 12C, the insulating resin is removed from the upper side toward the lower side and, further, the support member 11 of the electronic part-containing element 10 is also removed. Therefore, the electrode 15 of the circuit module 12 is exposed. The electrode 15 can be exposed by various methods. Preferred methods include, for example, grinding, reactive ion etching (RIE), chemical-mechanical polishing (CMP) and wet etching.

After the electrode is exposed, the wiring circuit 22 can be directly formed on the electrode 15 that is formed as shown in FIG. 12D. The wiring circuit 22 can be formed by, for example, the nonelectrolytic copper plating and the electrolytic copper plating.

According to an alternative method, as shown in FIG. 12E, a build-up resin 33 is deposited on the formed electrode 15, a viahole is perforated at a portion of the wiring by using a laser beam to thereby form a wiring circuit 34. The wiring circuit 34 can be formed by, for example, the nonelectrolytic copper plating and the electrolytic copper plating.

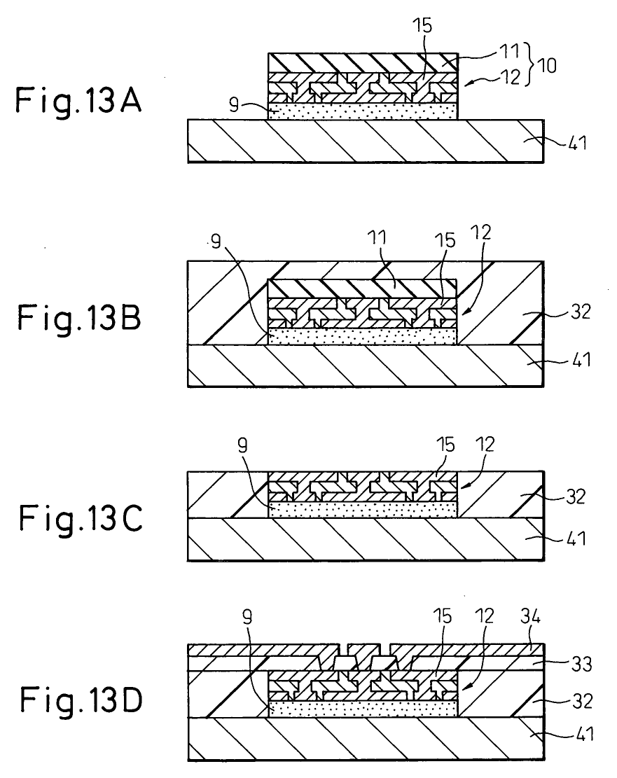

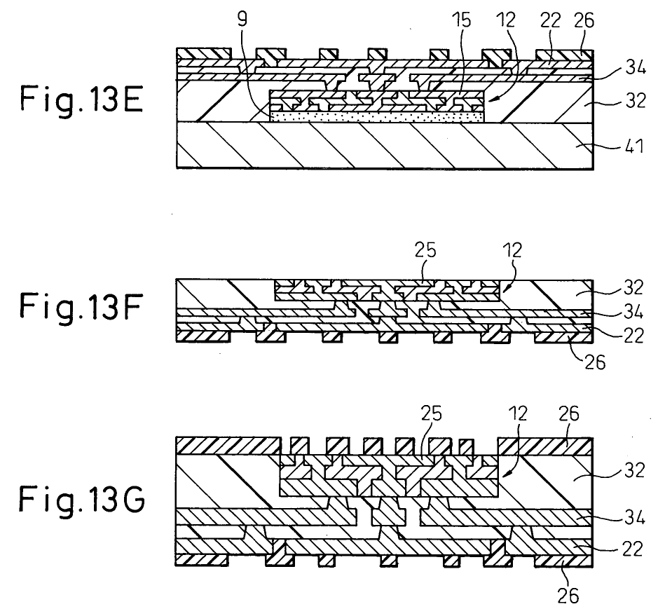

FIGS. 13A to 13G are sectional views illustrating, successively, a method of producing the electronic device of FIG. 8 by using the electronic part-containing element of the present invention.

Referring, first, to FIG. 13A, the electronic part-containing element 10 of the invention is placed on a board 41 for temporary mounting that has been formed in advance with the support member 11 on the upper side, and is fixed thereto by using the fixing material 9 which is the die-attachment film. The board 41 used here is desirably made of a material which has rigidity and can be removed by etching or polishing. As a suitable rigid board, there can be exemplified the one made of, for example, copper or nickel. In order that the rigid board can be repetitively used, further, there may be used a composite board obtained by sticking a thin plate of copper or the like onto the glass board by using a double-sided adhesive tape.

Referring, next, to FIG. 13B, the board 41 is covered with an insulating resin 32 to seal the electronic part-containing element 10. The insulating resin used here may be a resin material that is usually used for forming an interlayer insulating film in the production of electronic devices and may be, for example, an ABF resin manufactured by Ajinomoto Co.

Referring, next, to FIG. 13C, the insulating resin is removed from the upper side toward the lower side and, further, the support member 11 of the electronic part-containing element 10, too, is removed. Therefore, the electrode 15 of the circuit module 12 is exposed. The electrode 15 can be exposed by various methods. Preferred methods include, for example, grinding, reactive ion etching (RIE), chemical-mechanical polishing (CMP) and wet etching.

After the electrode is exposed, a build-up resin 33 is deposited on the electrode 15 as shown in FIG. 13D, and a viahole is perforated at a portion of the wiring by using a laser beam to thereby form a build-up wiring layer 34. The build-up wiring layer 34 can be formed by, for example, the nonelectrolytic copper plating and the electrolytic copper plating.

Thereafter, as shown in FIG. 13E, the building-up is effected again on the resulting build-up wiring layer 34 to thereby form a build-up wiring layer 22 and an insulating layer 26. The build-up wiring layer 22 can be formed by, for example, the nonelectrolytic copper plating and the electrolytic copper plating.

Thereafter, as shown in FIG. 13F, the whole device is turned around, and the board 41 on the upper side and the underlying fixing member 9 are successively removed. The board can be removed by various methods. When the board is made of, for example, copper, there can be used a method such as etching or polishing. When the board is made of, for example, silicon, there can be used a method such as polishing, CMP or etching. To remove the fixing member, further, there can be used a method such as polishing, RIE or peeling.

After removal of the board 41 and the fixing member 9, as shown in FIG. 13G, a pattern of the insulating layer 26 is formed as an uppermost layer to obtain the illustrated build-up wiring board.

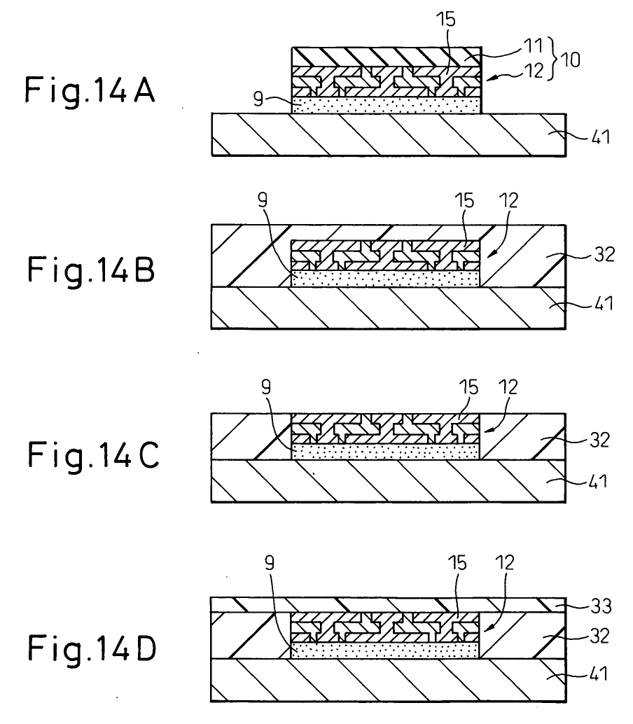

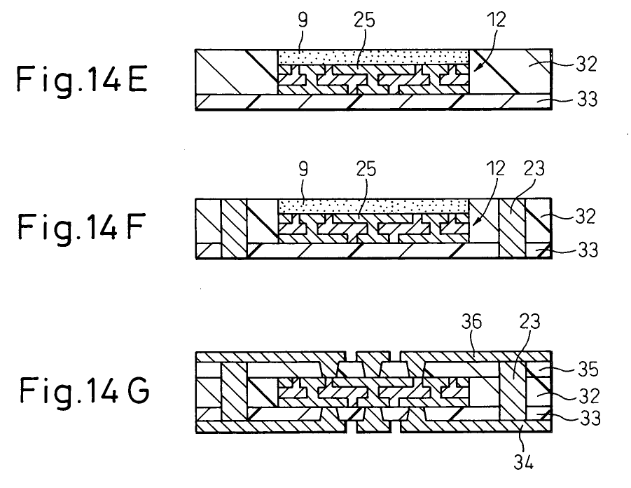

FIGS. 14A to 14G are sectional views illustrating, successively, methods of producing the electronic devices of FIGS. 9 and 10 by using the electronic part-containing element of the present invention.

Referring, first, to FIG. 14A, the electronic part-containing element 10 of the invention is placed on the board 41 for temporary mounting that has been formed in advance with the support member 11 on the upper side, and is fixed thereto by using the fixing material 9 which is the die-attach film. The board 41 used here is desirably made of a material which has rigidity and can be removed by etching or polishing. As a suitable rigid board, there can be exemplified the one made of, for example, copper or nickel as described above.

Referring, next, to FIG. 14B, the board 41 is covered with an insulating resin 32 to seal the electronic part-containing element 10. The insulating resin used here may be a resin material that is usually used for forming an interlayer insulating film in the production of electronic devices and may be, for example, an ABF resin manufactured by Ajinomoto Co.

Referring, next, to FIG. 14C, the insulating resin is removed from the upper side toward the lower side and, further, the support member 11 of the electronic part-containing element 10, too, is removed. Therefore, the electrode 15 of the circuit module 12 is exposed. The electrode 15 can be exposed by various methods. Preferred methods include, for example, grinding, reactive ion etching (RIE), chemical-mechanical polishing (CMP) and wet etching.

After the electrode is exposed, a build-up resin 33 is deposited on the resulting electrode 15 as shown in FIG. 14D.

Thereafter, as shown in FIG. 14E, the whole device is turned around, and the board 41 on the upper side is successively removed. The board can be removed by various methods. When the board is made of, for example, copper, there can be used such a method as etching or polishing. When the board is made of, for example, silicon, there can be used a method such as polishing, CMP or etching.

Thereafter, as shown in FIG. 14F, a through hole is perforated at a predetermined position of the insulating resin 32 and the build-up resin 33, and is filled with copper that is plated to thereby form a conducting core 23. Though not shown, the fixing material 9 is removed, and a build-up resin is deposited on the above portion. To remove the fixing material, further, there can be used such a method as polishing, RIE or peeling. The step of depositing the resin may be omitted, and the fixing material itself may be used as the build-up resin.

Finally, as shown in FIG. 14G, a viahole is made at a predetermined portion of forming the wiring in the build-up resins 33 and 35 by using a laser beam, and build-up wiring layers 34 and 36 are formed. These build-up wiring layers can be formed by, for example, the nonelectrolytic copper plating and the electrolytic copper plating.

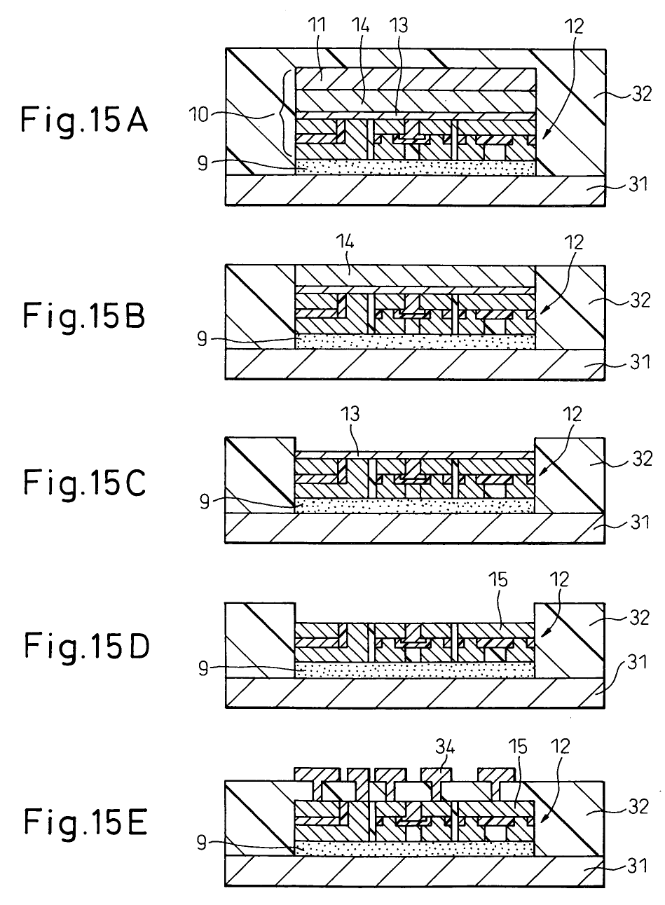

FIGS. 15A to 15E are sectional views illustrating, successively, a method of producing an electronic device by using the electronic part-containing element of FIG. 5.

Referring, first, to FIG. 15A, the electronic part-containing element 10 of the invention is placed on the underlying layer 31 that has been formed in advance with the support member 11 on the upper side, and is fixed thereto by using the fixing material 9 which is the die-attachment film. The underlying layer 31 in this embodiment is a core layer of the multi-layer wiring board. Next, the underlying layer 31 is covered with the insulating resin 32 to seal the electronic part-containing element. The insulating resin used here may be a resin material that is usually used for forming an interlayer insulating film in the production of electronic devices and may be, for example, an ABF resin manufactured by Ajinomoto Co.

Referring, next, to FIG. 15B, the insulating resin is removed from the upper side toward the lower side and, further, the support member 11 of the electronic part-containing element 10, too, is removed. Therefore, the etch-out layer 14 of the electronic part-containing element 10 is exposed. The etch-out layer 14 can be exposed by various methods. Preferred methods are, for example, grinding, reactive ion etching (RIE), chemical-mechanical polishing (CMP) and wet etching.

Thereafter, as shown in FIG. 15C, the etch-out layer 14 exposed to the surface is selectively removed by etching to expose the underlying barrier layer 13. Thereafter, as shown in FIG. 15D, the barrier layer 13 is also removed by etching. Therefore, the electrode 15 of the circuit module 12 is exposed.

After the electrode is exposed as described above, a build-up wiring layer 34 is formed on the resulting electrode 15 as shown in FIG. 15E. In this step, for example, the build-up resin is deposited, a viahole is perforated in a predetermined portion for forming wiring by using a laser beam, and the build-up wiring layer 34 is formed. The build-up wiring layer 34 can be formed by, for example, the nonelectrolytic copper plating and the electrolytic copper plating.

1. An electronic part-containing element used by being incorporated in an electronic device, in which said electronic part-containing element comprises a support member which does not take part in the constitution of the electronic device but is removed in the process of producing the electronic device, and a circuit module supported by said support member, and said circuit module contains one or more electronic parts each in the form of a thin film, and has connection terminals for said electronic parts at least on the surface thereof that comes in contact with said support member.

2. An electronic part-containing element according to claim 1, wherein said electronic part is an active element and/or a passive element.

3. An electronic part-containing element according to claim 2, wherein said active element is a semiconductor element.

4. An electronic part-containing element according to claim 2, wherein said passive element is a member selected from the group consisting of an inductor, a capacitor and a resistor.

5. An electronic part-containing element according to claim 2, wherein said passive element is a composite circuit of an inductor, a capacitor and a resistor.

6. An electronic part-containing element according to claim 1, wherein said circuit module further comprises through-type electrodes.

7. An electronic part-containing element according to claim 1, wherein said circuit module has connection terminals for said electronic part on both the first surface thereof that comes in contact with said support member and on the second surface thereof opposite to said first surface.

8. An electronic part-containing element according to claim 1, wherein said circuit module has a thickness of not larger than 50 μm.

9. An electronic part-containing element according to claim 1, wherein said circuit module further comprises an etching-resistant barrier layer and an etch-out layer formed successively on the surface thereof that comes in contact with said support member.

10. A method of producing an electronic part-containing element used by being incorporated in an electronic device, which comprises:
providing a support member which does not take part in the constitution of the electronic device but is removed in the process of producing the electronic device; and
forming a circuit module on said support member, wherein one or more electronic parts are fabricated by utilizing a thin film-forming technology in said circuit module, and connection terminals for said electronic part are formed at least on the surface of said circuit module that comes in contact with said support member.

11. A method of producing an electronic part-containing element according to claim 10, wherein said active element and/or passive element is fabricated as said electronic part.

12. A method of producing an electronic part-containing element according to claim 11, wherein said active element is a semiconductor element.

13. A method of producing an electronic part-containing element according to claim 11, wherein said passive element is a member selected from the group consisting of an inductor, a capacitor and a resistor.

14. A method of producing an electronic part-containing element according to claim 11, wherein said passive element is a composite circuit of an inductor, a capacitor and a resistor.

15. A method of producing an electronic part-containing element according to claim 10, wherein in forming said circuit module, the connection terminals for said electronic part are formed on both the first surface thereof that comes into contact with said support member and on the second surface thereof opposite to said first surface.

16. An electronic device having incorporated therein one or more electronic parts each in the form of a thin film, wherein said electronic part is a member of an electronic part-containing circuit module that is formed by incorporating, in any portion of said electronic device, an electronic part-containing element which comprises a circuit module containing said electronic part therein and a support member supporting said circuit module, and has connection terminals for said electronic part at least on the surface of said circuit module that comes in contact with said support member, followed by removing said support member in the process of producing said electronic device.

17. An electronic device according to claim 17, wherein said electronic part is an active element and/or a passive element.

18. An electronic device according to claim 17, wherein said active element is a semiconductor element.

19. An electronic device according to claim 17, wherein said passive element is selected from the group consisting of an inductor, a capacitor and a resistor.

20. An electronic device according to claim 17, wherein said passive element is a composite circuit of an inductor, a capacitor and a resistor.

21. An electronic device according to claim 16, wherein said circuit module further comprises through-type electrodes.

22. An electronic device according to claim 16, wherein said circuit module has connection terminals for said electronic part on both the first surface thereof that comes into contact with said support member and on the second surface thereof opposite to said first surface.

23. An electronic device according to claim 16, wherein said circuit module further comprises an etching-resistant barrier layer and an etch-out layer formed successively on the surface thereof that comes in contact with said support member, and said barrier layer and said etch-out layer are removed in the process of producing said electronic device.

24. An electronic device according to claim 16, wherein said electronic part-containing circuit module is incorporated as a member of the wiring board.

25. An electronic device according to claim 24, wherein said wiring board is a multi-layer wiring board, and said electronic part-containing circuit module is incorporated in the uppermost layer and/or the core layer of said multi-layer wiring board.

26. An electronic device according to claim 16, wherein said electronic part is electrically connected to wiring circuit, electrode, or other conducting pattern through electrically conducting viaholes.

27. A method of producing an electronic device having incorporated therein one or more electronic parts each in the form of a thin film, comprising:
incorporating, in any portion of said electronic device, an electronic part-containing element which comprises a circuit module containing said electronic part therein and a support member supporting said circuit module, and has connection terminals for said electronic part at least on the surface of said circuit module that comes in contact with said support member; and
providing an electronic part-containing circuit module by removing said support member in the process of producing said electronic device.

28. A method of producing an electronic device according to claim 27, wherein said electronic part-containing element is produced by forming a support member which does not take part in the constitution of the electronic device but is removed in the process of producing the electronic device, forming a circuit module on said support member, fabricating one or more electronic parts by utilizing a thin film-forming technology in said circuit module while said circuit module is being formed, and forming connection terminals for said electronic part at least on the surface of said circuit module that comes in contact with said support member.

29. A method of producing an electronic device according to claim 27, wherein said electronic part is an active element and/or a passive element.

30. A method of producing an electronic device according to claim 29, wherein said active element is a semiconductor element.

31. A method of producing an electronic device according to claim 29, wherein said passive element is selected from the group consisting of an inductor, a capacitor and a resistor.

32. A method of producing an electronic device according to claim 29, wherein said passive element is a composite circuit of an inductor, a capacitor and a resistor.

33. A method of producing an electronic device according to claim 27, wherein in forming said circuit module, the connection terminals for said electronic part are formed on both the first surface thereof that comes in contact with said support member and on the second surface thereof opposite to said first surface.

34. A method of producing an electronic device according to claim 27, wherein in forming the wiring board, said electronic part-containing circuit module is incorporated as a member of the wiring board.

35. A method of producing an electronic device according to claim 34, wherein a multi-layer wiring board is formed as said wiring board, and said electronic part-containing circuit module is incorporated in the uppermost layer and/or the core layer of said multi-layer wiring board.

36. A method of producing an electronic device according to claim 27, wherein said electronic part is electrically connected to a wiring circuit, electrode or other conducting pattern through electrically conducting viaholes.

37. A method of producing an electronic device according to claim 27 wherein, after said electronic part-containing element is fixed to the board in a manner that the said support member is exposed upward, said electronic device is completed through a subsequent series of processing steps and machining steps, and said support member is removed in any of said processing steps or machining steps.
